(19) United States
(12) Patent Application Publication
(10) Pub. No.: US 2010/0231235 A1
(43) Pub. Date: Sep. 16, 2010

(54) RESONANCE ELECTRIC CURRENT DETECTION SYSTEM

(76) Inventor: Kang-Seok Cho, Gyeonggi-do (KR)

Correspondence Address: LADAS & PARRY LLP, 26 WEST 61ST STREET, NEW YORK, NY, 10023, US

(21) Appl. No.: 12/279,748

(22) PCT Filed: Jan. 24, 2007
(86) PCT No.: PCT/KR07/00415

§ 371 Date: Aug. 18, 2008

(30) Foreign Application Priority Data
Mar. 13, 2006 (KR) 10-2006-0023082

(51) Int. Cl. G01R 27/04

(52) U.S. Cl. 324/633

(57) ABSTRACT

A resonance electric current detection apparatus is disclosed. The above apparatus comprises a detection unit which detects an electric current by a resonance of an inductor L and a capacitor C and outputs to a control unit, and a control unit which controls an electric current detected by the detection unit. With the above construction, It is possible to easily perform a LC resonance electric current control, a speaker network resonance control, an automatic gain control and a LED control by forming the detected resonance electric current as a load circuit or controlling a surge voltage which is generated in a non-load state.

### TECHNICAL FIELD

The present invention relates to a resonance electric current detection system, and in particular to a resonance electric current detection system which is used to detect an electric current by resonance of an inductor L and a capacitor C and to control a LC resonance electric current using the detected electric current and to be used for an automatic gain control and a speaker network resonance control.

### BACKGROUND ART

Generally, a resonance circuit is designed to electrically generate a resonance phenomenon, which occurs when a frequency of a free vibration occurring by a reverse conversion between different energies is very closer to a frequency of an external force. It is referred to as a tuned circuit. In a coil (inductor) and a condenser (capacitor), an electric resonance is generated at a certain frequency which is determined by a coil (inductor) and a condenser. An electric characteristic of a coil (inductor) and a condenser (capacitor) visually disappears, so that a circuit is formed based on only a small level of quantum electric resistances.

The resonance circuit generally refers to a circuit in which an electrostatic energy of a capacitor C and an electromagnetic energy of an inductance L can be freely converted. The resonance circuit is basically formed of, a serial resonance circuit in which a capacitor C and an inductor L are connected in series, and a parallel resonance circuit which is connected in parallel with the above serial resonance circuit.

Here, the resonance frequency f₀ is a

$$\frac{1}{2 Π \sqrt{LC}} [ Hz ]$$

where L is [L](Henry), and C is [F] (Farad). The impedance with respect to an external force of the frequency is 0 in a serial connection and is limitless in a parallel connection. So, a high level electric current occurs with a small level voltage in the serial connection, and a high level voltage is generated with a small level electric current in the parallel connection.

Various technologies are adapted to the above resonance circuit. Namely, such technologies are disclosed in the Korean patent registration number 10-0279625 (title of the invention: resonance deviation prevention circuit of resonance type converter), the Korean patent laid-open number 10-2005-0076619 (title of the invention: resonance type switch power apparatus), and the Korean utility model registration number 20-0258120 (title of the utility model: high frequency resonance inverter having high efficiency).

According to the conventional apparatus for detecting a resonance electric current based on the resonance circuit, it is implemented by using a method which detects a resonance electric current by a leakage inductance of a transformer and a capacitance of a resonance capacitor or by using a method which detects a generation of a high frequency resonance at a load R in a state that a capacitor connected in parallel with a switching device, an inductance for a LC resonance with the capacitor and a load R are connected with each other in parallel.

However, the above conventional resonance electric current detection apparatuses based on a resonance circuit have complicated constructions, and more manpower and higher cost are needed for constructing the above circuits. The resonance circuit is determined based on a load resistance and a cut-off frequency, but a surge voltage is disadvantageously generated by a cut-off frequency in a non-load state.

### DISCLOSURE OF INVENTION

Accordingly, it is an object of the present invention to provide a resonance electric current detection apparatus which overcomes the above-described problems.

It is another object of the present invention to provide a resonance electric current detection apparatus in which a resonance electric current generated by a resonance of an inductor L and a capacitor C can be easily detected by a simple circuit construction, and a LC resonance electric current control and a speaker network resonance control can be performed by forming the detected electric current as a load, and it is possible to control a surge voltage and an automatic gain control operation, which are generated in a non-load state, by using a simple circuit construction.

### BRIEF DESCRIPTION OF THE DRAWINGS

The present invention will become better understood with reference to the accompanying drawings which are given only by way of illustration and thus are not limitative of the present invention, wherein;

FIG. 1 is a view illustrating the whole construction of a resonance electric current detection apparatus according to a preferred embodiment of the present invention; and

FIG. 2 is a view illustrating an electric current control apparatus which uses a resonance electric current detection apparatus according to an embodiment of the present invention.

### BEST MODE FOR CARRYING OUT THE INVENTION

In an electric current detection apparatus, there is provided a resonance electric current detection apparatus which comprises a detection unit which detects an electric current by a resonance of an inductor L and a capacitor C and outputs to a control unit, and a control unit which controls the detected electric current from the detection unit.

The resonance electric current detection apparatus according to a preferred embodiment of the present invention will be described with reference to the accompanying drawings.

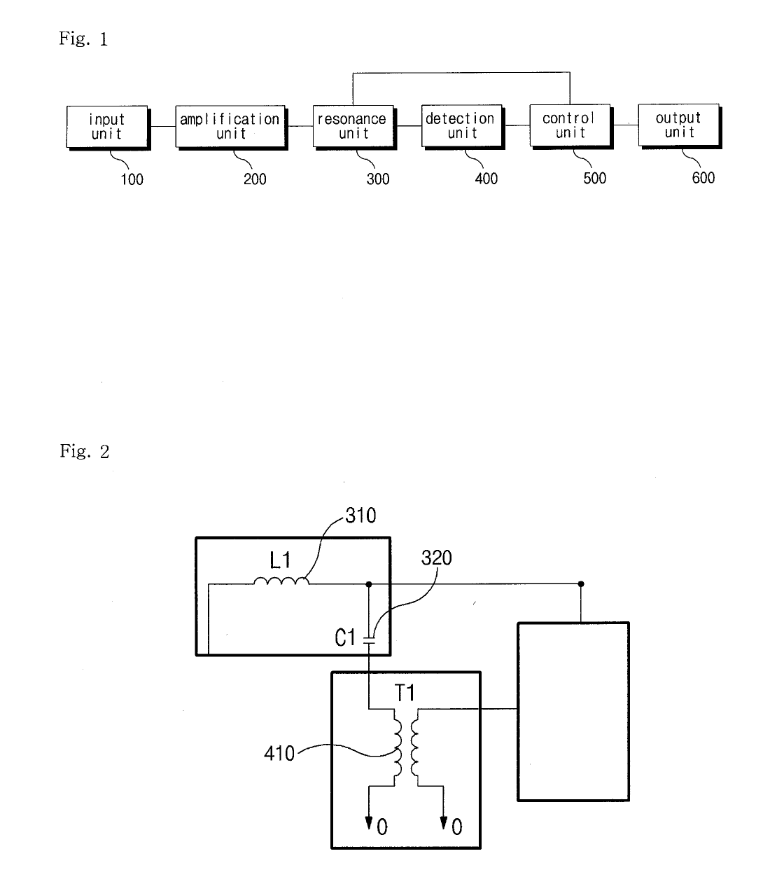

FIG. 1 is a view illustrating the whole construction of a resonance electric current detection apparatus according to a preferred embodiment of the present invention. The above construction will be described in more detains with reference to FIG. 1.

The resonance electric current detection apparatus according to the present invention comprises a detection unit 400, and a control unit 500.

The detection unit 400 detects a resonance electric current that an inductor 310 and a capacitor 320 of a resonance unit 300 generate based on a serial resonance or parallel resonance and is connected with an output terminal (not shown) at which an electric current generated by a serial resonance or a parallel resonance of the inductor 310 and the capacitor 320 is outputted, so that an inductive electric current.

In particular, the detection unit 400 is preferably formed of a transformer 410. The transformer 410 is connected with an end of the capacitor 320 for detecting an electric current which is generated by a serial resonance or a parallel resonance of the inductor 310 and the capacitor 320 and receives an inductive electric current which is applied through the capacitor 320 and transmits the received inductive electric current to the control unit 500.

The control unit 500 is connected with the detection unit 400, namely, the transformer, for thereby receiving the resonance electric current, and performs various functions using the received resonance electric current.

In particular, a certain load circuit is automatically formed by using a surge voltage which is generated by a cut-off frequency in a non-load state for thereby controlling a digital amplifier LC resonance and performing a function such as a speaker network resonant control.

Even when there is a change in the input of the receiver or the amplifier, it is possible to perform various functions such as an automatic gain control and LED control using the received resonance electric current as a control voltage so that the gain becomes uniform.

The operation of the resonance electric current detection apparatus according to the present invention will be described with reference to the accompanying drawings.

FIG. 2 is a view illustrating an electric current control apparatus which uses a resonance electric current detection apparatus according to an embodiment of the present invention.

As shown therein, a preferred embodiment of the present invention, which includes a resonance electric current detection apparatus of the present invention, preferably comprises an input unit 100, an amplification unit 200, a resonance unit 300, a detection unit 400, a control unit 500 and an output unit 600.

When an electric current is received from the input unit 100 and is transmitted to the amplification unit 200, the amplification unit 200 controls an inputted electric current and transmits to the resonance unit 300.

The resonance unit 300 is constructed in such a manner that a serial resonance or a parallel resonance is formed by an inductor L and a capacitor C, so that a resonance is generated by using an electric current transmitted. In the present invention, a serial resonance is more preferable.

The electric current generated by the resonance unit 300 flows to the detection unit 400 through the capacitor 320, and the detection unit 400 receives the electric current and detects an inductive electric current.

In particular, the detection unit 400 is formed of a transformer 410. An inductive electric current is generated by using the inputted electric current for thereby detecting an electric current.

The inductive electric current generated by the detection unit 400 is transmitted to the control unit 500, and the control unit 500 performs various functions using the inputted electric current.

In particular, various different functions may be obtained by changing the construction of the control unit 500. A load circuit may be automatically formed by using a surge voltage based on a cut-off frequency in a non-load state. The digital amplification LC resonance may be controlled by using the output unit 600. A speaker network resonance control may be performed. An automatic gain control may be performed so that a gain is uniform by using the received electric current as a control voltage. In addition, a LED control function may be also obtained.

### INDUSTRIAL APPLICABILITY

As described above, in the resonance electric current detection apparatus according to the present invention, a resonance electric current detection circuit is simplified. A resonance electric current can be detected by using a simple circuit construction, so that manpower and cost may be significantly decreased. It is possible to easily perform a LC resonance electric current control, a speaker network resonance control, an automatic gain control and a LED control by forming the detected resonance electric current as a load circuit or controlling a surge voltage which is generated in a non-load state.

As the present invention may be embodied in several forms without departing from the spirit or essential characteristics thereof, it should also be understood that the above-described examples are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

1. In an electric current detection apparatus, a resonance electric current detection apparatus, comprising:
a detection unit which detects an electric current by a resonance of an inductor L and a capacitor C and outputs to a control unit; and
a control unit which controls an electric current detected by the detection unit.

2. The apparatus of claim 1, wherein said detection unit detects an electric current by either a serial resonance or a parallel resonance of the inductor L and a capacitor C.

3. The apparatus of claim 1, wherein said detection unit detects an inductive electric current in such a manner that a transformer is connected with an output terminal at which an electric current is outputted by either a serial resonance or a parallel resonance of the inductor L and the capacitor C.

4. The apparatus of claim 1, wherein said control unit forms a load circuit by the electric current detected by the detection unit and controls a resonance of the inductor L and the capacitor C using the same.
